(19) United States
(12) Patent Application Publication
(10) Pub. No.: US 2023/0269957 A1
(43) Pub. Date: Aug. 24, 2023

(54) ORGANIC ELECTROLUMINESCENT DEVICE, DISPLAY PANEL AND DISPLAY APPARATUS

(71) Applicant: BOE Technology Group Co., Ltd., Beijing (CN)

(72) Inventors: Lixia QIU, Beijing (CN); Lei CHEN, Beijing (CN); Yang LIU, Beijing (CN)

(21) Appl. No.: 17/921,318

(22) PCT Filed: Jul. 5, 2021
(86) PCT No.: PCT/CN2021/104431

§ 371 Date: Oct. 25, 2022

(30) Foreign Application Priority Data
Aug. 28, 2020 (CN) 202010887673.9

(51) Int. Cl. H10K 50/16; H10K 50/12; H10K 50/18; H10K 59/35

(52) U.S. Cl. CPC H10K 50/16; H10K 50/12; H10K 50/18; H10K 59/35; H10K 2101/30

(57) ABSTRACT

An organic electroluminescent device, a display panel and a display apparatus. The organic electroluminescent device comprises: an anode and a cathode, which are arranged opposite each other; an organic electroluminescent layer, which is located between the anode and the cathode; a hole blocking layer, which is located between the organic electroluminescent layer and the cathode; and an electron transport layer, which is located between the hole blocking layer and the cathode, wherein the organic electroluminescent layer comprises: an exciplex formed by means of mixing an electron-type light-emitting host material and a hole-type light-emitting host material, and a light-emitting guest material doped in the exciplex; and the electron mobility of the electron transport layer is greater than that of the hole blocking layer, and the electron mobility of the hole blocking layer is greater than that of the electron-type light-emitting host material.

### CROSS REFERENCE TO RELATED APPLICATIONS

This application claims the priority of Chinese Patent Application No. 202010887673.9, filed to China National Intellectual Property Administration on Aug. 28, 2020 and entitled “ORGANIC ELECTROLUMINESCENT DEVICE, DISPLAY PANEL AND DISPLAY APPARATUS”, the entire contents of which are incorporated herein by reference.

### FIELD

The present disclosure relates to the technical field of display, in particular to an organic electroluminescent device, a display panel and a display apparatus.

### BACKGROUND

In recent years, organic light-emitting diodes (OLEDs) have received more attention as a new type of flat panel display. Due to its characteristics of active luminescence, high luminous brightness, high resolution, wide viewing angle, fast response, color saturation, thinness and lightness, low energy consumption, and flexibility, it is hailed as fantasy display and becomes a hot mainstream display product currently on the market.

### SUMMARY

In one aspect, an embodiment of the present disclosure provides an organic electroluminescent device, including an anode and a cathode which are oppositely disposed, an organic electroluminescent layer between the anode and the cathode, a hole blocking layer between the organic electroluminescent layer and the cathode, and an electron transport layer between the hole blocking layer and the cathode; wherein, the organic electroluminescent layer includes an exciplex formed by mixing an electron-type light-emitting host material and a hole-type light-emitting host material, and a light-emitting guest material doped in the exciplex; and an electron mobility of the electron transport layer is greater than an electron mobility of the hole blocking layer, and the electron mobility of the hole blocking layer is greater than an electron mobility of the electron-type light-emitting host material.

Optionally, in the above organic electroluminescent device provided by the embodiment of the present disclosure, a ratio of the electron mobility of the electron transport layer to the electron mobility of the hole blocking layer is greater than or equal to 10.

Optionally, in the above organic electroluminescent device provided by the embodiment of the present disclosure, a ratio of the electron mobility of the hole blocking layer to the electron mobility of the electron-type light-emitting host material is greater than or equal to 10.

Optionally, in the above organic electroluminescent device provided by the embodiment of the present disclosure, the electron mobility of the electron transport layer is in a range of 10⁻⁷ cm² V⁻¹ S⁻¹ to 10⁻⁴ cm² V⁻¹ S⁻¹.

Optionally, in the above organic electroluminescent device provided by the embodiment of the present disclosure, the electron mobility of the hole blocking layer is in a range of 10⁻⁸ cm² V⁻¹ S⁻¹ 10⁻⁶ cm² V⁻¹ S⁻¹.

Optionally, in the above organic electroluminescent device provided by the embodiment of the present disclosure, the electron mobility of the electron-type light-emitting host material is in a range of 10⁻⁹ cm² V⁻¹ S⁻¹ 10⁻⁷ cm² V⁻¹ S⁻¹.

Optionally, in the above organic electroluminescent device provided by the embodiment of the present disclosure, an absolute value of a difference between a LUMO value of the hole blocking layer and a LUMO value of the electron transport layer is greater than or equal to 0.15 eV and less than or equal to 0.9 eV; an absolute value of a difference between the LUMO value of the hole blocking layer and a LUMO value of the electron-type light-emitting host material is greater than or equal to 0.01 eV and less than or equal to 0.5 eV; and the hole blocking layer has a triplet energy level of greater than or equal to 2.4 eV and the electron transport layer has a triplet energy level of greater than or equal to 2.4 eV.

Optionally, in the above organic electroluminescent device provided by the embodiment of the present disclosure, the absolute value of the difference between the HOMO value of the hole blocking layer and the HOMO value of the electron transport layer is greater than or equal to 0.01 eV and less than or equal to 0.5 eV; and the absolute value of the difference between the HOMO value of the hole blocking layer and the HOMO value of the electron-type light-emitting host material is greater than or equal to 0.05 eV and less than or equal to 0.8 eV.

Optionally, in the above organic electroluminescent device provided by the embodiment of the present disclosure, an energy level difference between a triplet energy level and a singlet energy level of the exciplex is less than or equal to 0.2 eV.

Optionally, in the above organic electroluminescent device provided by the embodiment of the present disclosure, an emission spectrum peak of the hole-type light-emitting host material is greater than or equal to 350 nm and less than or equal to 460 nm; an emission spectrum peak of the electron-type light-emitting host material is greater than or equal to 400 nm and less than or equal to 490 nm; and an emission spectrum peak of the exciplex is greater than or equal to 500 nm and less than or equal to 580 nm.

Optionally, in the above organic electroluminescent device provided by the embodiment of the present disclosure, a mass ratio of the hole-type light-emitting host material to the electron-type light-emitting host material is in a range of 1:10 to 10:1.

Optionally, in the above organic electroluminescent device provided by the embodiment of the present disclosure, a doping ratio of the light-emitting guest material in the organic electroluminescent layer is in a range of 2%-10%.

Optionally, in the above organic electroluminescent device provided by the embodiment of the present disclosure, the organic electroluminescent layer is a red light-emitting layer or a green light-emitting layer.

In another aspect, an embodiment of the present disclosure also provides a display panel, including: a plurality of sub-pixel units, wherein at least part of the sub-pixel units includes the above organic electroluminescent device.

Optionally, in the above display panel provided by the embodiment of the present disclosure, each of the sub-pixel units include: a red sub-pixel unit, a green sub-pixel unit, and a blue sub-pixel unit; wherein, the red sub-pixel unit and the green sub-pixel unit include the above organic electroluminescent device, and the blue sub-pixel unit includes a blue organic electroluminescent device; an organic electroluminescent layer of the blue organic electroluminescent device includes an electron-hole type light-emitting host material and a blue light guest material; hole blocking layers of all of the sub-pixel units are in a same film layer and electron transport layers of all of the sub-pixel units are in a same film layer; an absolute value of a difference between a LUMO value of the hole blocking layer and a LUMO value of the electron-hole type light-emitting host material is greater than or equal to 0.2 eV and less than or equal to 0.5 eV; and a triplet energy level of the electron-hole type light-emitting host material is less than or equal to that of the blue light guest material.

In another aspect, an embodiment of the present disclosure also provides a display apparatus, including the above display panel.

### BRIEF DESCRIPTION OF THE DRAWINGS

FIG. 1 is a structural schematic diagram of an organic electroluminescent device according to an embodiment of the present disclosure.

FIG. 2 is a schematic diagram of an energy level relationship of an organic electroluminescent device according to an embodiment of the present disclosure.

FIG. 3 is an emission spectrogram of an organic electroluminescent device according to an embodiment of the present disclosure.

FIG. 4 is a first structural schematic diagram of an array substrate according to an embodiment of the present disclosure.

FIG. 5 is a second structural schematic diagram of an array substrate according to an embodiment of the present disclosure.

### DETAILED DESCRIPTION OF THE EMBODIMENTS

In order to make objectives, technical solutions and advantages of the embodiments of the present disclosure clearer, the technical solutions of the embodiments of the present disclosure are described clearly and completely below with reference to the drawings of the embodiments of the present disclosure. It should be noted that sizes and shapes of all figures in the drawings do not reflect a true scale and are only intended to illustrate contents of the present disclosure. Same or similar reference signs throughout denote same or similar elements or elements with same or similar functions. Obviously, the described embodiments are some, not all, of the embodiments of the present disclosure. Based on the described embodiments of the present disclosure, all other embodiments obtained by those of ordinary skill in the art without creative efforts fall within the protection scope of the present disclosure.

Unless otherwise defined, technical or scientific terms used herein shall have the ordinary meaning as understood by those of ordinary skill in the art to which the present disclosure belongs. “First”, “second” and similar words used in the specification and the claims of the present disclosure do not represent any order, quantity, or importance, but are merely used to distinguish different components. “Include” or “comprise” and other similar words mean that an element or an item preceding the word covers elements or items and their equivalents listed behind the word without excluding other elements or items. “Inner”, “outer”, “upper”, “lower”, etc. are only used to indicate a relative positional relationship, and when an absolute position of a described object changes, the relative positional relationship may also change accordingly.

With the continuous development of OLED products, the requirements for the performance of the OLED products such as the efficiency and service life are getting higher and higher. The performance of a light-emitting device mainly depends on the material itself performance of each film layer and a device matching structure, wherein the material direction mainly takes into account material mobility, material stability, material fluorescence quantum yield (PLQY), etc., and the device matching structure direction mainly takes into account energy level matching of adjacent film layers, exciton distribution, electron and hole injection and accumulation, etc. For problems of lower efficiency and service life of a device, it is currently believed that a main incentive lies in poor stability of a material of a light-emitting layer (EML) and accumulation of electrons at the interface of the light-emitting layer (EML)/a hole blocking layer (HBL).

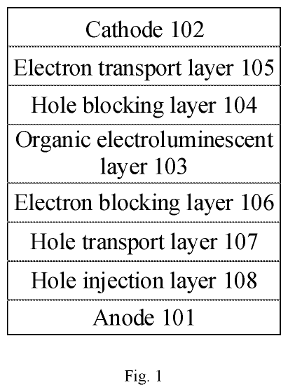

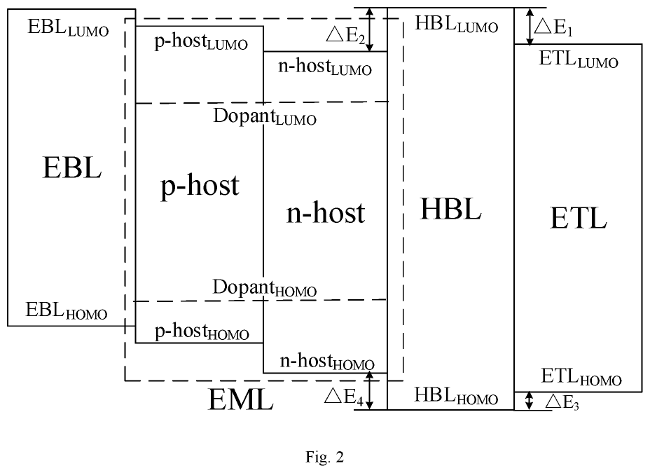

With respect to the above-mentioned problems existing in the related art, an embodiment of the present disclosure provides an organic electroluminescent device, as shown in FIGS. 1 and 2, including an anode 101 and a cathode 102 which are oppositely disposed, an organic electroluminescent layer 103 between the anode 101 and the cathode 102, a hole blocking layer 104 between the organic electroluminescent layer 103 and the cathode 102, and an electron transport layer 105 between the hole blocking layer 104 and the cathode 102.

The organic electroluminescent layer 103 includes an exciplex formed by mixing an electron-type light-emitting host material n-host and a hole-type light-emitting host material p-host, and a light-emitting guest material dopant doped in the exciplex.

It should be noted that the electron-type light-emitting host material n-host refers to a material having an electron mobility higher than a hole mobility; and the hole-type light-emitting host material p-host refers to a material having a hole mobility greater than an electron mobility.

An electron mobility of the electron transport layer 105 is greater than an electron mobility of the hole blocking layer 104, and an electron mobility of the hole blocking layer 104 is greater than an electron mobility of the electron-type light-emitting host material n-host.

In the above organic electroluminescent device provided by the embodiment of the present disclosure, on one hand, by disposing that the electron mobility of the electron transport layer 105 is greater than that of the hole blocking layer 104, an injection barrier of electrons transported from the electron transport layer 105 to the hole blocking layer 104 is increased, and too much, too fast transport of electrons to the hole blocking layer 104 is avoided. On the other hand, it is provided that the electron mobility of the hole blocking layer 104 is greater than that of the electron-type light-emitting host material n-host, so that electrons can be easily transported from the hole blocking layer 104 to the organic electroluminescent layer 103. The combined effect of the above two aspects effectively avoids accumulation of electrons at the interface of the organic electroluminescent layer 103 and the hole blocking layer 104, and makes electrons move better to the inside of the organic electroluminescent layer 103, thereby improving the efficiency and the service life of the organic electroluminescent device.

Optionally, in the above organic electroluminescent device provided by the embodiment of the present disclosure, in order to effectively control the transport rate of electrons, it may be provided that a ratio of an electron mobility of the electron transport layer 105 to an electron mobility of the hole blocking layer 104 is greater than or equal to 10, for example, 10, 100, or the like.

Optionally, in the above organic electroluminescent device provided by the embodiment of the present disclosure, in order to increase the probability that electrons and holes form excitons in the organic electroluminescent layer 103, a ratio of an electron mobility of the hole blocking layer 104 to an electron mobility of the electron-type light-emitting host material n-host may be made to be greater than or equal to 10.

Optionally, the electron mobility of the electron transport layer 105 of the above organic electroluminescent device provided by the embodiment of the present disclosure is in a range of 10⁻⁷ cm² V⁻¹ S⁻¹ to 10⁻⁴ cm² V⁻¹ S⁻¹, for example, 10⁻⁷ cm² V⁻¹ S⁻¹, 10⁻⁶ cm² V⁻¹ S⁻¹, 10⁻⁵ cm² V⁻¹ S⁻¹, 10⁻⁴ cm² V⁻¹ S⁻¹, or the like. The electron mobility of the hole blocking layer 104 is in a range of 10⁻⁸ cm² V⁻¹ S⁻¹ to 10⁻⁶ cm² V⁻¹ S⁻¹, for example, 10⁻⁸ cm² V⁻¹ S⁻¹, 10⁻⁷ cm² V⁻¹ S⁻¹, 10⁻⁶ cm² V⁻¹ S⁻¹, or the like. The electron mobility of the electron-type light-emitting host material in a range of n-host is 10⁻⁹ cm² V⁻¹ S⁻¹ to 10⁻⁷ cm² V⁻¹ S⁻¹, for example, 10⁻⁹ cm² V⁻¹ S⁻¹, 10⁻⁸ cm² V⁻¹ S⁻¹, 10⁻⁷ cm² V⁻¹ S⁻¹, or the like.

Optionally, in the above organic electroluminescent device provided by the embodiment of the present disclosure, as shown in FIG. 2, an absolute value ΔE1 of a difference between a lowest unoccupied molecular orbital (LUMO) value (HBL_{LUMO}) of the hole blocking layer 104 and a LUMO value (ETL_{LUMO}) of the electron transport layer 105 is greater than or equal to 0.15 eV and less than or equal to 0.9 eV.

Optionally, an absolute value ΔE2 of a difference between the LUMO value (HBL_{LUMO}) of the hole blocking layer 104 and a LUMO value (n-host_{LUMO}) of the electron-type light-emitting host material n-host is greater than or equal to 0.01 eV and less than or equal to 0.5 eV.

Optionally, the hole blocking layer 104 has a triplet energy level T1_{HBL} of greater than or equal to 2.4 eV and the electron transport layer 105 has a triplet energy level T1_{ETL} of greater than or equal to 2.4 eV.

The above energy level relationship not only helps to control the injection rate of electrons from the electron transport layer 105 into the hole blocking layer 104, but also facilitates the transport of electrons on the electron-type light-emitting host material n-host, so that the electrons are effectively confined in the organic electroluminescent layer 103 to recombine with holes to form excitons so as to emit light, and an exciton recombination region moves toward the center of the organic electroluminescent layer 103.

Optionally, in the above organic electroluminescent device provided by the embodiment of the present disclosure, as shown in FIG. 2, an absolute value ΔE3 of a difference between a HOMO value of the hole blocking layer 104 (HBL_{HOMO}) and a HOMO (highest occupied molecular orbital) value of the electron transport layer 105 (ETL_{HOMO}) is greater than or equal to 0.01 eV and less than or equal to 0.5 eV; and an absolute value ΔE4 of a difference between the HOMO value (HBL_{HOMO}) of the hole blocking layer 104 and a HOMO value (n-host_{HOMO}) of the electron-type light-emitting host material is greater than or equal to 0.05 eV and less than or equal to 0.8 eV.

This HOMO energy level relationship does not hinder the hole blocking action of the hole blocking layer 104, so that electrons can be efficiently recombined with holes in the organic electroluminescent layer 103 to form excitons so as to emit light.

Optionally, in the above organic electroluminescent device provided by the embodiment of the present disclosure, an energy level difference ΔEST between a triplet energy level T1_{exciplex} and a singlet energy level S1_{exciplex} of the exciplex is less than or equal to 0.2 eV, that is, the exciplex has thermally activated delayed fluorescence (TADF) and has higher luminous efficiency.

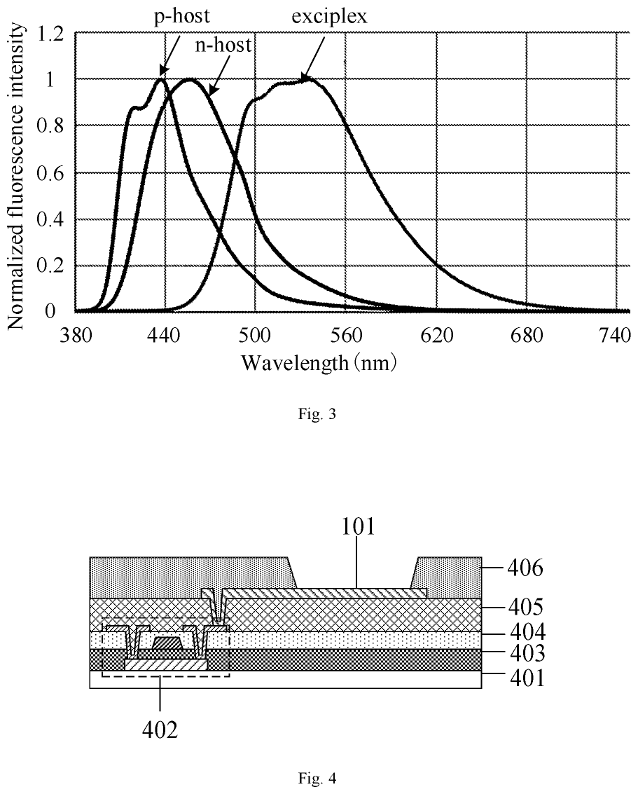

Optionally, in the above organic electroluminescent device provided by the embodiment of the present disclosure, as shown in FIG. 3, an emission spectrum peak (PL peak) of the hole-type light-emitting host material p-host is greater than or equal to 350 nm and less than or equal to 460 nm.

Optionally, an emission spectrum peak (PL peak) of the electron-type light-emitting host material n-host is greater than or equal to 400 nm and less than or equal to 490 nm.

Optionally, an emission spectrum peak (PL peak) of the exciplex is greater than or equal to 500 nm and less than or equal to 580 nm.

In the related art, a host material of a red light-emitting layer (R_EML) uses an electron-hole type single-host system, and the efficiency of the system can no longer meet the current mass production requirements. The light-emitting device provided by the present disclosure may have higher efficiency and service life. And from the above emission spectra, the present disclosure is applicable to a red phosphorescent system and a green phosphorescent system. That is, the organic electroluminescent layer 103 in the present disclosure may be a red light-emitting layer or a green light-emitting layer. In addition, in the case where a green organic electroluminescent device and a red organic electroluminescent device employ the structure of the device provided by the present disclosure, the overall performance of a panel can be better improved.

Optionally, in the above organic electroluminescent device provided by the embodiment of the present disclosure, a mass ratio of the hole-type light-emitting host material p-host to the electron-type light-emitting host material n-host is in a range of 1:10 to 10:1, for example, 1:10, 10:10, 10:1, or the like. The hole-type light-emitting host material p-host and the electron-type light-emitting host material n-host satisfying the above mass ratio can better capture electrons at the interface of the hole blocking layer 104 and the organic electroluminescent layer 103, and the electrons are transported to the inside of the organic electroluminescent layer 103 to enable recombination with holes to generate excitons within the organic electroluminescent layer 103 such that the exciton recombination region is away from the interface of the hole blocking layer 104 and the organic electroluminescent layer 103.

Optionally, in the above organic electroluminescent device provided by the embodiment of the present disclosure, a doping ratio of the light-emitting guest material is in the organic electroluminescent layer is in a range of 2% to 10%, for example, 2%, 3%, 4%, 5%, 6%, 7%, 8%, 9%, 10%, or the like. On one hand, the doping ratio enables the light-emitting host material (including the hole-type light-emitting host material p-host and the electron-type light-emitting host material n-host) to efficiently transfer the energy of the excitons to the light-emitting guest material dopant to excite the light-emitting guest material to emit light, on the other hand, the light-emitting host material (including the hole-type light-emitting host material p-host and the electron-type light-emitting host material n-host) “dilutes” the light-emitting guest material, effectively improving fluorescence quenching caused by the collision between molecules of the light-emitting guest material and the collision between energies, improving the luminous efficiency and device service life.

Optionally, the above organic electroluminescent device provided by the embodiment of the present disclosure, as shown in FIG. 1, may further generally include an electron blocking layer 106 between the anode 101 and the organic electroluminescent layer 103, a hole transport layer 107 between the electron blocking layer 106 and the anode 101, and a hole injection layer 108 between the hole transport layer 107 and the anode 101. Additionally, in some embodiments, an electron injection layer between the cathode 102 and the electron transport layer 105 can also be included.

Optionally, in the above organic electroluminescent device provided by the embodiment of the present disclosure, the electron transport layer 105 may be made of a mixture of an electron transport type material such as a nitrogen-containing heterocyclic compound (e.g., Bphen, and TPBi) and lithium 8-hydroxyquinolate (LiQ). A material of the hole blocking layer 104 can be a triazine compound, BAlq, or the like. Optionally, the hole-type light-emitting host material p-host may be TCP, CBP, mCP or the like. Optionally, the electron-type light-emitting host material n-host may be a nitrogen-containing heterocyclic compound or a cyano-containing aromatic heterocyclic compound or the like. Optionally, a red light-emitting guest material may be an organometallic complex, preferably an iridium metal complex and a platinum metal complex, such as Ir(ppy)₂(acac), Ir(ppy)₃, and the like. Optionally, the electron blocking layer 106 may be made of an arylamine compound. Optionally, the hole transport layer 107 may be made of an arylamine compound such as NPB, TPD, and the like. Optionally, the hole injection layer 108 may be a single-component film layer such as HATCN, CuPc, MoO₃ and the like, or a doped film layer such as a radialene-or quinone-doped arylamine compound, specifically F₄TCNQ-doped NPB or TPD. Wherein structural formulas of Bphen, TPBi, LiQ, BAlq, TCP, CBP, mCP, Ir(ppy)₃, Ir(ppy)₂(acac), NPB, TPD, HATCN, CuPc, and F4TCNQ are as follows.

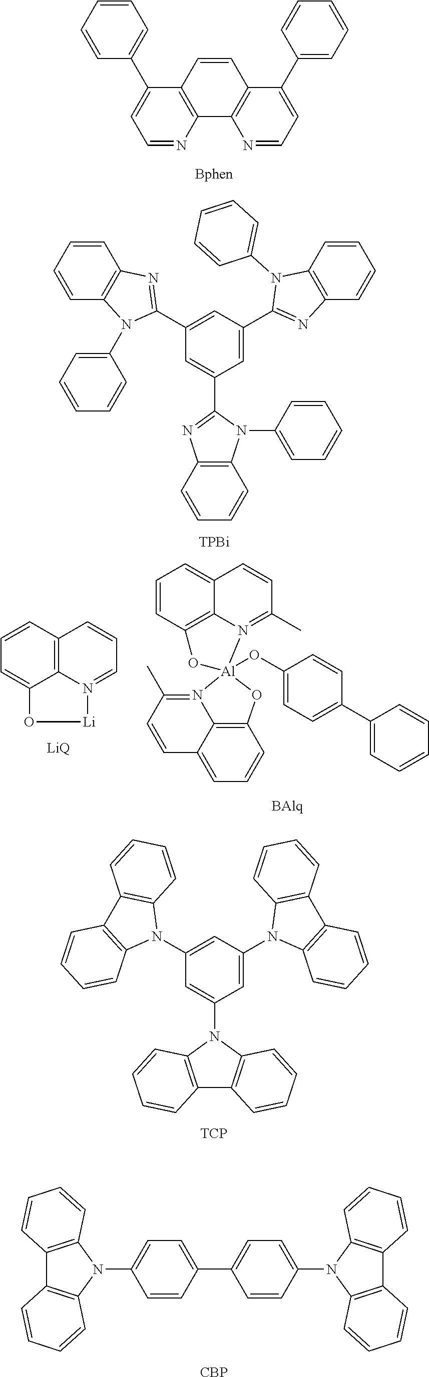

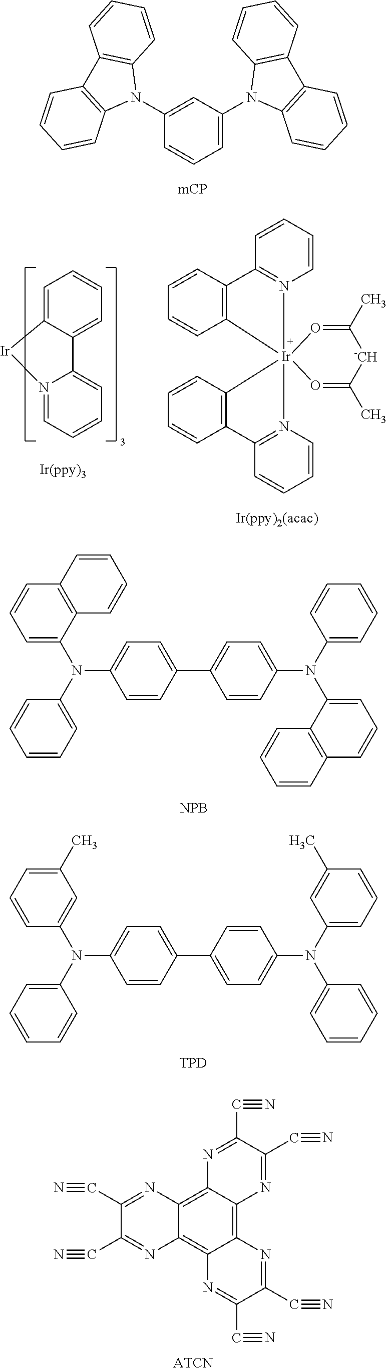

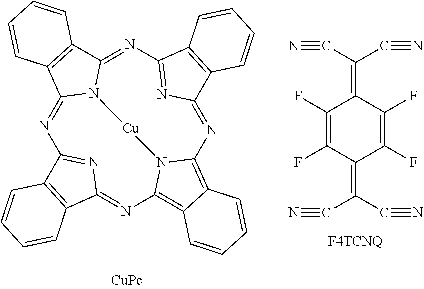

In addition, the device service life and efficiency of the present disclosure are described below with reference to the manufacture of a red organic electroluminescent device as an example.

In particular, a red organic electroluminescent device can be manufactured by the following method.

Step 1: a pixel driving circuit and an anode 101 electrically connected to the pixel driving circuit are formed on a substrate 401, as shown in FIG. 4. Specifically, the pixel driving circuit includes a plurality of transistors and at least one storage capacitor , and specifically shown in FIG. 4 is a drive transistor 402 electrically connected to the anode 101. Generally, as shown in FIG. 4, a gate insulator layer 403, an interlayer dielectric layer 404, a planarization layer 405, and a pixel defining layer 406 may also be included.

Step 2: A hole injection layer 108 having a thickness of 5-20 nm, and a hole transport layer 107 having a thickness of 80-120 nm are sequentially evaporated on a layer where the anode 101 is located by using a metal mask (an open mask).

Step 3: An electron blocking layer 106 having a thickness in a range of 20 to 100 nm, and an organic electroluminescent layer emitting red light 103 having a thickness in a range of 20 to 70 nm are sequentially evaporated on the hole transport layer 107 by using a fine metal mask (FMM), wherein a doping mass ratio of a red light-emitting guest material in the organic electroluminescent layer 103 is in a range of 2% to 10%, a mass ratio of a hole-type light-emitting host material p-host to an electron-type light-emitting host material n-host is in a range of 1:10 to 10:1, or a light-emitting host material of the organic electroluminescent layer 103 is an electron-hole type single host material (Single).

Step 4: A hole blocking layer 104 having a thickness in a range of 5 to 20 nm and an electron transport layer 105 having a thickness in a range of 20 to 50 nm are sequentially evaporated on the organic electroluminescent layer 103 by using a metal mask (an open mask).

Step 5: A cathode 102 made of a metal material is evaporated on the electron transport layer 105 by using a metal mask (an open mask).

Specifically, one comparative example and three embodiments are made in the present disclosure by using the manufacture method described above, wherein materials of the hole injection layer, the hole transport layer, the electron blocking layer, the hole blocking layer, the electron transport layer, and the cathode in the comparative example are the same as those in Embodiments, and specifically, the electron transport layer is composed of an electron-transport type material and lithium 8-hydroxyquinolate at a mass ratio of 5:5; the difference is only in the organic electroluminescent layer. The detailed parameters are shown in Table 1.

TABLE 1

| | Comparative | Embodi- | Embodi- | Embodi- |
|---|---|---|---|---|
| | example | ment 1 | ment 2 | ment 3 |
| Hole injection | 20 nm | 20 nm | 20 nm | 20 nm |
| layer | | | | |
| Hole transport | 100 nm | 100 nm | 100 nm | 100 nm |
| layer | | | | |
| Electron blocking | 5 nm | 5 nm | 5 nm | 5 nm |
| layer | | | | |
| Organic | Single | p-host: | p-host: | p-host: |
| electroluminescent | 45 nm | n-host (2:8) | n-host (5:5) | n-host (8:2) |
| layer | | 45 nm | 45 nm | 45 nm |
| Hole blocking | 10 nm | 10 nm | 10 nm | 10 nm |
| layer | | | | |
| Electron transport | 30 nm | 30 nm | 30 nm | 30 nm |
| layer | | | | |
| Cathode | 12 nm | 12 nm | 12 nm | 12 nm |

The performance data of devices in the above Comparative example and Embodiments 1-3 are shown in Table 2.

TABLE 2

| | Comparative | | | |
|---|---|---|---|---|
| | example | Embodiment 1 | Embodiment 2 | Embodiment 3 |
| Voltage | 100% | 94% | 95% | 97% |
| Efficiency | 100% | 140% | 155% | 148% |
| Service life | 100% | 150% | 200% | 180% |

As can be seen from Table 2, the efficiency and service life of devices in Embodiments 1-3 provided by the present disclosure are greatly improved.

Based on the same inventive concept, an embodiment of the present disclosure also provides a display panel, including: a plurality of sub-pixel units, wherein at least part of the sub-pixel units includes the above organic electroluminescent device. Since the principle of solving the problem of the display panel is similar to that of the organic electroluminescent device described above, the implementation of the display panel can refer to the embodiment of the organic electroluminescent device described above, and repetitions are omitted.

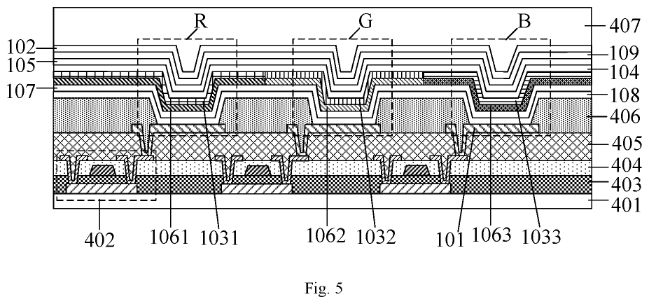

Optionally, in the above display panel provided by the embodiment of the present disclosure, as shown in FIG. 5, the sub-pixel units include: a red sub-pixel unit R, a green sub-pixel unit G, and a blue sub-pixel unit B.

The red sub-pixel unit R and the green sub-pixel unit G include the above organic electroluminescent device, and the blue sub-pixel unit B includes a blue organic electroluminescent device.

An organic electroluminescent layer of the blue organic electroluminescent device includes an electron-hole type light-emitting host material (BH) and a blue light guest material (BD).

Hole injection layers 108 of all of the sub-pixel units are in a same film layer, hole transport layers 107 of all of the sub-pixel units are in a same film layer, hole blocking layers 104 of all of the sub-pixel units are in a same film layer, electron injection layers 109 of all of the sub-pixel units are in a same film layer, electron transport layers 105 of all of the sub-pixel units are in a same film layer, an electron blocking layer and an organic electroluminescent layer of each sub-pixel unit are independent from each other, and in FIG. 5, 1061 represents an electron blocking layer of the red sub-pixel unit R, 1062 represents an electron blocking layer of the green sub-pixel unit G, and 1063 represents an electron blocking layer of the blue sub-pixel unit B; and 1031 represents an organic electroluminescent layer of the red sub-pixel unit R, 1032 represents an organic electroluminescent layer of the green sub-pixel unit G, and 1033 represents an organic electroluminescent layer of the blue sub-pixel unit B.

Wherein an absolute value of a difference between a LUMO value (HBL_{LUMO}) of the hole blocking layer and a LUMO value (BH_{LUMO}) of the electron-hole type light-emitting host material is greater than or equal to 0.2 eV and less than or equal to 0.5 eV; and the triplet energy level T1_{BH} of the electron-hole type light-emitting host material (BH) is smaller than or equal to the triplet energy level T1_{BD} of the blue light guest material (BD).

A blue organic electroluminescent device satisfying the above energy level relationship, in combination with a red organic electroluminescent device and a green organic electroluminescent device employing the structure of the device provided by the present disclosure, can achieve better white balance effects.

Based on the same inventive concept, an embodiment of the present disclosure also provides a display apparatus, including the above display panel provided by the embodiment of the present disclosure, and the display apparatus may be any product or part with a display function, such as a mobile phone, a tablet computer, a television, a display, a notebook computer, a digital photo frame, a navigator, a smart watch, a fitness wrist strap, and a personal digital assistant. Other essential components of the display apparatus should be understood by those of ordinary skill in the art and will not be described herein, nor should they be regarded as a limitation on the present disclosure. In addition, since the principle of solving the problem of the display apparatus is similar to that of the display panel, the implementation of the display apparatus may refer to the embodiment of the display panel, and repetitions are omitted.

According to the organic electroluminescent device, the display panel and the display apparatus provided by the embodiments of the present disclosure, the organic electroluminescent device includes: the anode and the cathode which are oppositely disposed, the organic electroluminescent layer between the anode and the cathode, the hole blocking layer between the organic electroluminescent layer and the cathode, and the electron transport layer between the hole blocking layer and the cathode; wherein the organic electroluminescent layer includes the exciplex formed by mixing the electron-type light-emitting host material and the hole-type light-emitting host material, and the light-emitting guest material doped in the exciplex; wherein the electron mobility of the electron transport layer is greater than that of the hole blocking layer, and the electron mobility of the hole blocking layer is greater than that of the electron-type light-emitting host material. In the above organic electroluminescent device provided by the embodiment of the present disclosure, on one hand, by disposing that the electron mobility of the electron transport layer is greater than that of the hole blocking layer, the injection barrier of electrons transported from the electron transport layer to the hole blocking layer is increased, and too much, too fast transport of electrons to the hole blocking layer is avoided; and on the other hand, it is provided that the electron mobility of the hole blocking layer is greater than that of the electron-type light-emitting host material, so that electrons can be easily transported from the hole blocking layer to the organic electroluminescent layer. The combined effect of the above two aspects effectively avoids accumulation of electrons at the interface of the organic electroluminescent layer and the hole blocking layer, and makes electrons move better to the inside of the organic electroluminescent layer, thereby improving the efficiency and the service life of the organic electroluminescent device.

Apparently, those skilled in the art can make various modifications and variations to the embodiments of the present disclosure without departing from the spirit and the scope of the embodiments of the present disclosure. Thus, if these modifications and variations of the embodiments of the present disclosure fall within the scope of the claims and their equivalents of the present disclosure, the present disclosure is also intended to include these modifications and variations.

1. An organic electroluminescent device, comprising an anode and a cathode which are oppositely disposed, an organic electroluminescent layer between the anode and the cathode, a hole blocking layer between the organic electroluminescent layer and the cathode, and an electron transport layer between the hole blocking layer and the cathode;
wherein:
the organic electroluminescent layer comprises an exciplex formed by mixing an electron-type light-emitting host material and a hole-type light-emitting host material, and a light-emitting guest material doped in the exciplex; and
an electron mobility of the electron transport layer is greater than an electron mobility of the hole blocking layer, and the electron mobility of the hole blocking layer is greater than an electron mobility of the electron-type light-emitting host material.

2. The organic electroluminescent device according to claim 1, wherein a ratio of the electron mobility of the electron transport layer to the electron mobility of the hole blocking layer is greater than or equal to 10.

3. The organic electroluminescent device according to claim 1, wherein a ratio of the electron mobility of the hole blocking layer to the electron mobility of the electron-type light-emitting host material is greater than or equal to 10.

4. The organic electroluminescent device according to claim 1, wherein the electron mobility of the electron transport layer is in a range of 10⁻⁷ cm² V⁻¹ S⁻¹ to 10⁻⁴ cm² V⁻¹ S⁻¹.

5. The organic electroluminescent device according to claim 1, wherein the electron mobility of the hole blocking layer is in a range of 10⁻⁸ cm² V⁻¹ S⁻¹ to 10⁻⁶ cm² V⁻¹ S⁻¹.

6. The organic electroluminescent device according to claim 1, wherein the electron mobility of the electron-type light-emitting host material is in a range of 10⁻⁹ cm² V⁻¹ S⁻¹ to 10⁻⁷ cm² V⁻¹ S⁻¹.

7. The organic electroluminescent device according to claim 1, wherein an absolute value of a difference between a lowest unoccupied molecular orbital (LUMO) value of the hole blocking layer and a LUMO value of the electron transport layer is greater than or equal to 0.15 eV and less than or equal to 0.9 eV;
an absolute value of a difference between the LUMO value of the hole blocking layer and a LUMO value of the electron-type light-emitting host material is greater than or equal to 0.01 eV and less than or equal to 0.5 eV; and
the hole blocking layer has a triplet energy level of greater than or equal to 2.4 eV and the electron transport layer has a triplet energy level of greater than or equal to 2.4 eV.

8. The organic electroluminescent device according to claim 1, wherein an absolute value of a difference between a (highest occupied molecular orbital) HOMO value of the hole blocking layer and a HOMO value of the electron transport layer is greater than or equal to 0.01 eV and less than or equal to 0.5 eV; and
an absolute value of a difference between the HOMO value of the hole blocking layer and a HOMO value of the electron-type light-emitting host material is greater than or equal to 0.05 eV and less than or equal to 0.8 eV.

9. The organic electroluminescent device according to claim 1, wherein an energy level difference between a triplet energy level and a singlet energy level of the exciplex is less than or equal to 0.2 eV.

10. The organic electroluminescent device according to claim 1, wherein an emission spectrum peak of the hole-type light-emitting host material is greater than or equal to 350 nm and less than or equal to 460 nm;
an emission spectrum peak of the electron-type light-emitting host material is greater than or equal to 400 nm and less than or equal to 490 nm; and
an emission spectrum peak of the exciplex is greater than or equal to 500 nm and less than or equal to 580 nm.

11. The organic electroluminescent device according to claim 1, wherein a mass ratio of the hole-type light-emitting host material to the electron-type light-emitting host material is in a range of 1:10 to 10:1.

12. The organic electroluminescent device according to claim 11, wherein a doping ratio of the light-emitting guest material in the organic electroluminescent layer is in a range of 2% to 10%.

13. The organic electroluminescent device according to claim 1, wherein the organic electroluminescent layer is a red light-emitting layer or a green light-emitting layer.

14. A display panel, comprising a plurality of sub-pixel units, wherein at least part of the sub-pixel units comprises the organic electroluminescent device according to claim 1.

15. The display panel according to claim 14, wherein each of the sub-pixel units comprise a red sub-pixel unit, a green sub-pixel unit, and a blue sub-pixel unit;
wherein:
the red sub-pixel unit and the green sub-pixel unit comprise the organic electroluminescent device, and the blue sub-pixel unit comprises a blue organic electroluminescent device;
an organic electroluminescent layer of the blue organic electroluminescent device comprises an electron-hole type light-emitting host material and a blue light guest material;
hole blocking layers of all of the sub-pixel units are in a same film layer and electron transport layers of all of the sub-pixel units are in a same film layer;
an absolute value of a difference between a lowest unoccupied molecular orbital (LUMO) value of the hole blocking layer and a LUMO value of the electron-hole type light-emitting host material is greater than or equal to 0.2 eV and less than or equal to 0.5 eV; and
a triplet energy level of the electron-hole type light-emitting host material is less than or equal to that of the blue light guest material.

16. A display apparatus, comprising the display panel according to claim 14.

17. The organic electroluminescent device according to claim 1, further comprising an electron blocking layer between the anode and the organic electroluminescent layer.

18. The organic electroluminescent device according to claim 17, further comprising a hole transport layer between the electron blocking layer and the anode.

19. The organic electroluminescent device according to claim 18, further comprising a hole injection layer between the hole transport layer and the anode.

20. The organic electroluminescent device according to claim 1, wherein the electron transport layer is made of a mixture of an electron transport type material and lithium 8-hydroxyquinolate (LiQ).
